(19) United States
(12) Patent Application Publication
(10) Pub. No.: US 2012/0097213 A1
(43) Pub. Date: Apr. 26, 2012

(54) BIFACIAL PHOTOVOLTAIC MODULE WITH REFLECTIVE ELEMENTS AND METHOD OF MAKING SAME

(75) Inventor: Stephen E. Weidner, Sylvania, OH (US)

(73) Assignee: PILKINGTON GROUP LIMITED, ST. HELENS (GB)

(21) Appl. No.: 13/261,071

(22) PCT Filed: Jun. 28, 2010
(86) PCT No.: PCT/US2010/001849

§ 371 Date: Dec. 9, 2011

Related U.S. Application Data
(60) Provisional application No. 61/221,678, filed on Jun. 30, 2009.

(51) Int. Cl. H01L 31/052

(52) U.S. Cl. 136/246

(57) ABSTRACT

For use in building and construction, a bifacial photovoltaic module having at least one reflective element disposed on a surface of a light transmitting substrate such that a portion of the solar radiation passing through the sheet of light-transmitting substrate is reflected off of the reflective element so as to be capable of conversion to electrical energy by a photoactive portion of the photovoltaic module.

### BACKGROUND OF THE INVENTION

The present invention relates to a photovoltaic module. More particularly, the present invention relates to a bifacial photovoltaic module having improved conversion efficiency.

Bifacial photovoltaic modules are known in the patent literature, for example:

U.S. Patent Publication No. 2006/0272698 describes an energy conversion system including a first optical cover having a flat surface and a patterned surface. The patterned surface is configured to receive solar energy from the flat surface, then concentrate and guide the solar energy. The system further includes a photovoltaic cell layer between the patterned surface of the first optical cover and the second optical cover. The photovoltaic cell layer is said to be configured to receive solar energy from the patterned surface for conversion into electrical energy.

U.S. Patent Publication No. 2007/0107773 describes a bifacial photovoltaic arrangement comprising a bifacial cell which includes a semiconductor layer having a first surface, and a second surface, a first passivation layer formed on the first surface of the semiconductor layer and a second passivation layer formed on the second surface of the semiconductor layer, and a plurality of metallizations formed on the first and second passivation layers and selectively connected to the semiconductor layer. At least some of the metallizations are said to have a relatively small width and a relatively large height extending upward from the first and second passivation layers.

U.S. Patent Publication No. 2008/0041436 describes a bifacial photovoltaic device including an electrically conductive and light reflective core, a plurality of semiconductor layers, a system of current-collecting surface electrodes and an anti-reflective layer.

U.S. Patent Publication No. 2008/0066801 describes a lightweight photovoltaic system made from a plurality of substantially rectangular photovoltaic modules consisting of a lightweight support board and a photovoltaic panel disposed in abutting relationship in rows and columns on a substrate and connected to each other by a dovetailing between frames connecting the support board to the panel with clamping strips holding down the photovoltaic panel on the frame, and at least one tension wire extending along one of the rows and columns as attached to a substructure for retaining the system.

U.S. Patent Publication No. 2008/0257399 describes a thin film solar cell and a method for fabricating the same. The solar cell has first and second transparent substrates, first and second solar cell modules, and an insulating layer. The first solar cell module is formed on the first transparent substrate, and has a metal layer as one of the electrodes of the first solar module, and as a light reflection layer. The insulating layer is said to be formed on the metal layer of the first solar cell module. The second solar cell module is said to be formed between the insulating layer and the second transparent substrate.

U.S. Patent Publication No. 2008/0257400 describes a holographically enhanced photovoltaic solar module including a first substrate having substantially parallel inner and outer major surfaces, the first substrate being optically transparent and having a transmission grating on the second major surface thereof, a second substrate having substantially parallel inner and outer major surfaces, having a reflection grating on the inner major surface thereof, and at least one solar cell interposed between the transmission grating and the reflection grating and oriented perpendicular thereto.

U.S. Patent Publication No. 2009/0120486 describes first and second solar panels mounted in an operative position, each panel including an upward-facing and a downward-facing photovoltaic surface configured to generate electricity from light. The downward-facing photovoltaic surface is spaced above a reflective surface. The first and second panels are spaced apart in a first direction by a spacing distance that is about 25% to about 100% of the width of the first panel in the first direction. It is said that some downwardly-directed light rays can strike the upward-facing photovoltaic surfaces of the panels. It is further said that other downwardly-directed light rays can pass between the first and second panels and be reflected upward by the reflective surface to strike the downward-facing photovoltaic surfaces of the panels.

### SUMMARY OF THE INVENTION

The present invention relates to an improved bi-facial photovoltaic module, which through utilization of at least one reflective element, more efficiently converts solar radiation to electrical energy than known photovoltaic modules in applications where both sides of the bi-facial module are not exposed to direct solar radiation.

More particularly, the photovoltaic (PV) module of the invention is comprised of a sheet of a substrate material having a first and a second major surface which is substantially transparent to solar radiation, for example soda-lime-silica glass. Over a first major surface of the light-transmitting substrate, a photoactive material is disposed. The photoactive material can be in the form of a coated polymeric film which is adhered to the first major substrate surface, or the photoactive material could be a multi-layer thin film coating stock disposed on the first major substrate surface. On the second major surface of the light-transmitting substrate, a material is disposed which is highly reflective, forming at least one reflective element, which reflects a portion of the solar radiation back through the sheet of light-transmitting substrate.

In other embodiments, the PV module of the invention can be a laminate structure with the PV material disposed between two glass sheets as described above, or it could be an insulated glass (IG) unit where the photoactive coating is disposed between two sheets of a light-transmitting material, which laminated assembly is separated from at least one glass sheet by a spacer/air/evacuated area, the non-laminated glass sheet having a reflective material disposed on one major surface thereof.

### BRIEF DESCRIPTION OF THE DRAWINGS

The above, as well as other advantages of the present invention will become readily apparent to those skilled in the art from the following detailed description when considered in the light of the accompanying drawings in which:

FIG. 1 shows a conventional bi-facial PV module as known in the art.

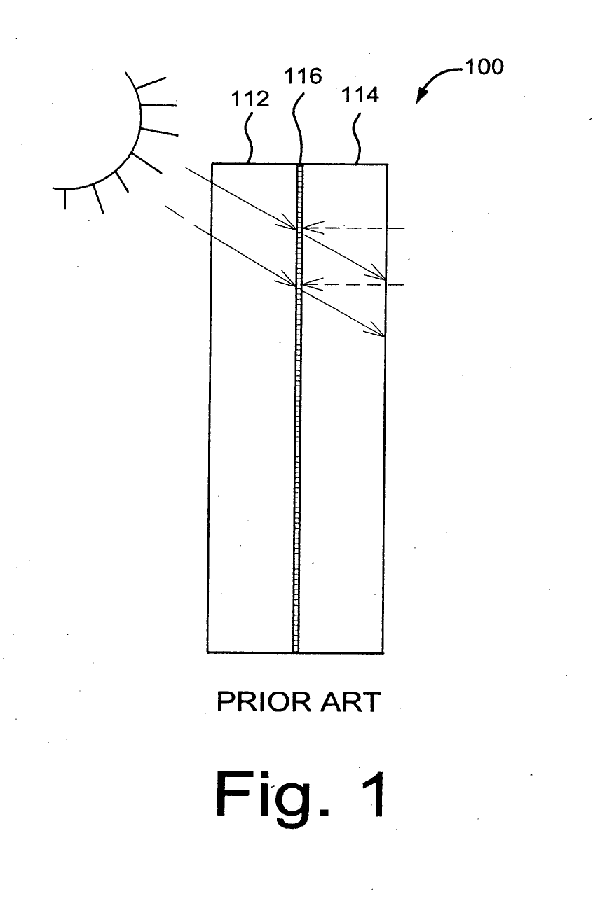

FIG. 2 illustrates a monolithic embodiment of a bi-facial PV module according to the invention.

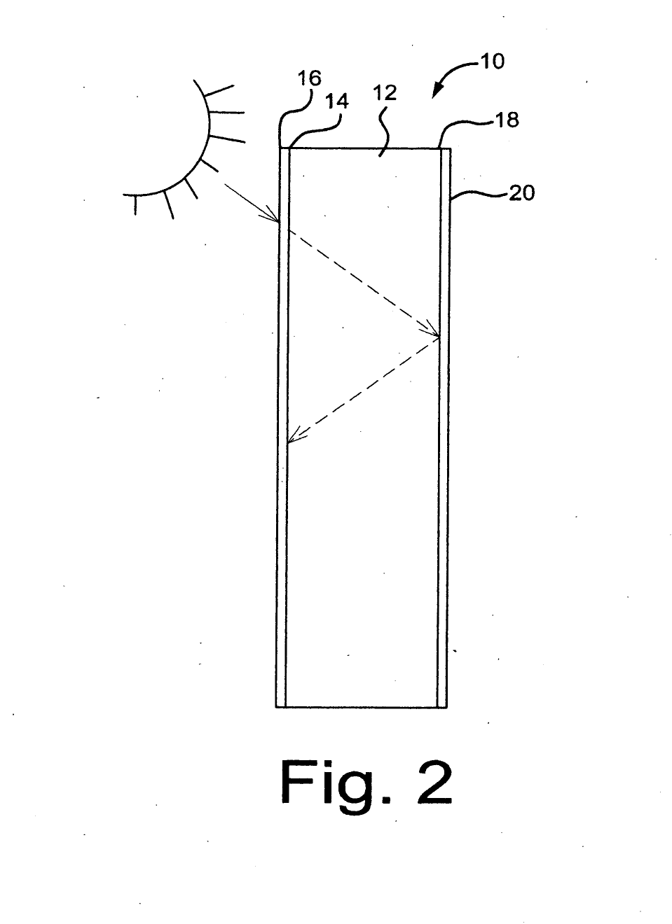

FIG. 3 illustrates a laminated structure embodiment of a bi-facial PV module according to the invention.

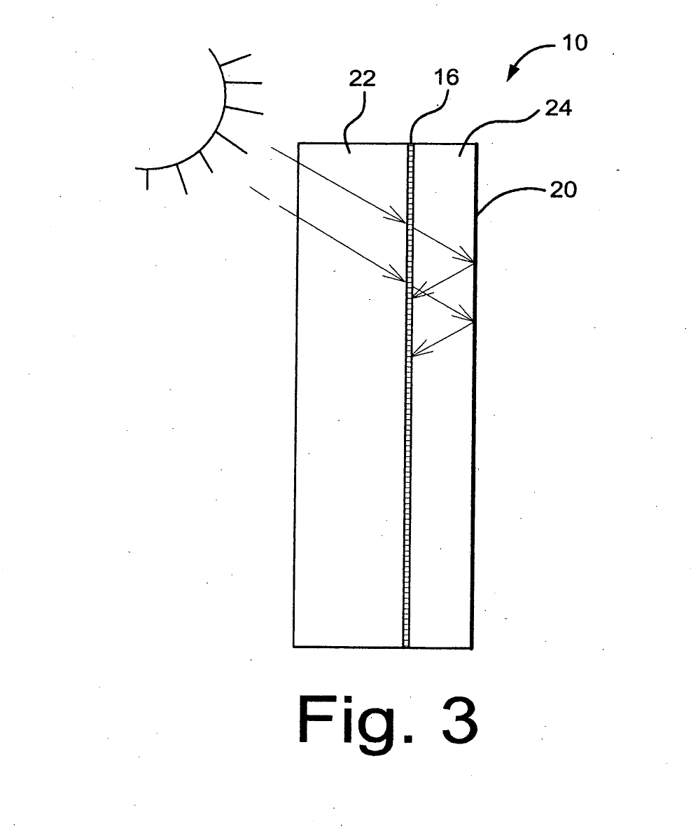

FIG. 4 illustrates an insulated glass (IG) unit embodiment of a bi-facial PV module according to the invention.

### DETAILED DESCRIPTION OF THE INVENTION

The present invention relates to an improved bifacial photovoltaic module 10 that, through utilization of at least one reflective element, more efficiently converts solar radiation to electrical energy than known photovoltaic modules.

More particularly, the photovoltaic (PV) module 10 of the invention comprises one or more sheets of a substrate material 12 which is substantially transparent to solar radiation, for example soda-lime-silica glass, preferably a minimally absorbing, low-iron soda-lime-silica glass. On a first major surface 14 of the at least one glass sheet 12, a photoactive material 16 is disposed. The photoactive material 16 can be in the form of a coated polymeric film which is adhered to the first major substrate surface 14, or the photoactive material 16 could be a multi-layer thin film coating stack disposed by, for example, chemical vapor deposition, vacuum sputtering, or other suitable deposition method on the first major substrate surface 14. On a second major surface 18 of one of the at least one glass sheet 12, a reflective layer 20 is disposed which is highly reflective of electromagnetic solar radiation above the band gap of the selected photoactive material. This reflective layer 20 preferably has a reflectivity of 75% or more of such radiation, and preferably 85% or more. The reflective layer 20 could be formed, as examples, of a thin film of a metal, metal oxide, or the like, a conventional glass mirror, or a polished metal sheet.

In other embodiments, the PV module 10 of the invention can be a laminate structure with the photoactive material 16 disposed between two glass sheets 22, 24, as described above, or it could be an insulated glass (IG) unit where the photoactive coating 16 is disposed between two sheets of a light-transmitting material 22, 24, which laminated assembly is separated from at least one glass sheet 26 by a spacer/air/evacuated area 28, the glass sheet 26 spaced across the gap 28 having a reflective material 20 disposed on one major surface thereof. Preferably, the reflective material 20 provided on this spaced sheet 26 provides at least a moderate reflectivity of electromagnetic solar radiation in the band gap of the selected photoactive material 16, preferably at least 15% of such radiation. Layer 20 may also be highly reflective as set forth above. The reflective material 20 is preferably provided on the #3 surface, but may also be provided on the exterior or #4 surface. In some embodiments, it may be preferable to form each of the sheets 22, 24, 26, so that the overall IG unit remains transparent.

Where the PV module 10 of the invention is a single sheet of a material substantially transparent to solar radiation 12 such as a low-iron soda-lime-silica glass, a photoactive material 16, for example, titanium oxide, cadmium/telluride, amorphous silicon, crystalline silica is preferably disposed on the first major surface 14 of the substrate, i.e., the major substrate surface in closest proximity to the direct source of infrared radiation. Where the photoactive material 16 is disposed on a sheet of polymeric material adhered to the substrate, such coated polymeric material could be for example, a mylar-type heat mirror film, PVB, PVC, EVA and the like. If the photoactive material 16 is deposited directly on the substrate surface 14, 18, by one of the methods set forth previously, it could be in the form of a multi-layer film stack, deposited by any suitable method including various CVD and sputter coating technologies.

In the single sheet 12, or monolithic, embodiment of the invention, a reflective material 20 such as silver, chromium and aluminum, is disposed on the second major surface 18 of the substrate 12, i.e., the surface most distant from the direct source of infrared radiation.

Where the reflective layer 20 has a reflectivity of 85% or more, and where the photoactive material 16 generally has a conversion efficiency of 7-8% or more, the incremental electrical energy generated by a PV module 10 according to the monolithic embodiment of the is estimated to be from 3% to 55% greater than known bifacial PV modules.

Where the bifacial PV module 10 of the invention is a laminate structure, many of the same materials as noted above for the monolithic embodiment may be utilized. As previously noted, it is preferred in the laminate embodiment that the PV material and the reflective material 20 are protected between the two glass sheets, which are adhesively bonded by any suitable bonding method which preserves the infrared light transmissive properties of the glass sheet closest to the direct source of infrared radiation. In a laminated embodiment, the incremental absorption or electrical energy which may be generated by the PV module according the invention preferably is from 3% to 55% greater than known bifacial PV modules. Of course other arrangements of the photoactive material 16 and reflective material 20 on the major surfaces of the at least two glass sheets of the laminate structure are possible.

Where the bifacial PV module 10 of the invention is an insulated glass unit two or more glass sheets 22, 24, 26, are arranged in a parallel, spaced apart relationship.

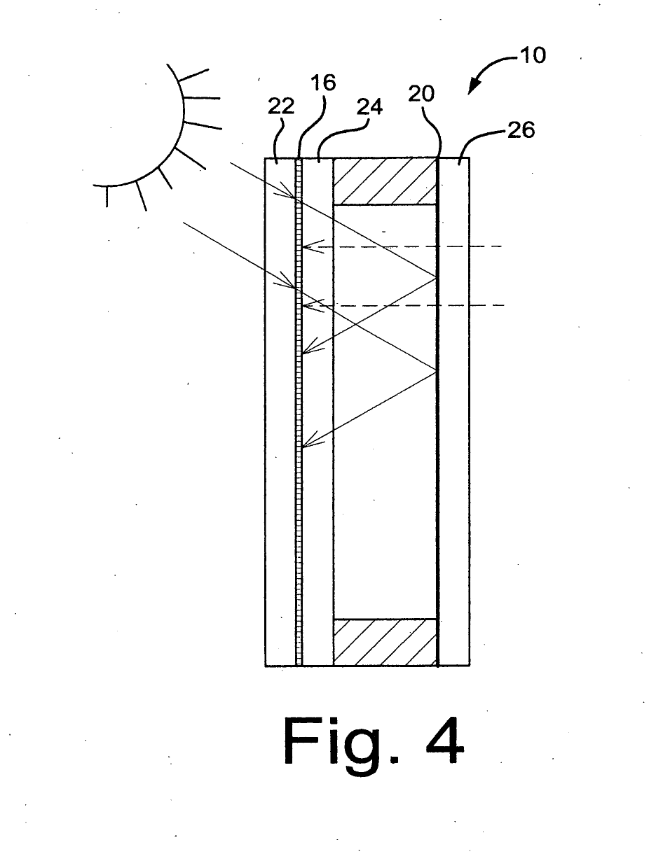

In one configuration, as shown in FIG. 4 the photoactive material 16 is preferably disposed on the second (#2) major surface of the glass sheet closest to the direct source of infrared radiation, which second surface is exposed to the space between the two glass sheets. As previously noted, the reflective material 20, is preferably disposed on the first major (#3) surface of the second glass sheet, such that it, like the photoactive material 16 is exposed to the space 30 between the two glass sheets. In this configuration, suitable photoactive materials 16 and suitable reflective materials 20 include, for example; those mentioned previously here. In this configuration the incremental absorption or electrical energy generated by the bifacial PV module 10 according to the invention is estimated to be from 2% to 50% greater than known bifacial PV modules.

### Examples

The benefits of use of the reflective element of the invention are illustrated by Table 1, where elements having increasing precent reflectance in a laminated bifacial PV assembly are calculated to increase light absorptance, particularly in the visible spectrum, more specifically at 550 nm. The increase in absorptance is based on utilization of a photo-active element Power Plastic® made by Konarka.

TABLE I

| | Laminate Assembly | | | | |
|---|---|---|---|---|---|
| | Structure | | | Visible Light | Increase in |
| | [coated surface in ( )] | | | Reflectance | absorptance |
| | 3 mm thick | | 3 mm thick | (%) | at 550 nm (%) |
| 1.* | Pilkington | Photoactive | Pilkington | 8% | baseline |
| | OptiWhite ™ | Element | OptiWhite ™ | | |
| | Low Iron | | Low Iron | | |
| | Glass | | Glass | | |
| 2. | Pilkington | Photoactive | Pilkington | 11% | 3% |
| | OptiWhite ™ | Element | Energy | | |
| | Low Iron | | Advantage ™ | | |
| | Glass | | Low-E (#4) | | |
| 3. | Pilkington | Photoactive | Pilkington | 29% | 13% |
| | OptiWhite ™ | Element | Eclipse | | |
| | Low Iron | | Advantage ™ | | |
| | Glass | | Clear (#4) | | |
| 4. | Pilkington | Photoactive | Pilkington | 78% | 34% |
| | OptiWhite ™ | Element | Mirage ™ | | |
| | Low Iron | | (#4) | | |
| | Glass | | | | |
| 5. | Pilkington | Photoactive | Silver Mirror | 90% | 55% |
| | OptiWhite ™ ™ | Element | (#4) | | |
| | Low Iron | | | | |
| | Glass | | | | |

*comparative example—not within the scope of the invention

In accordance with the provisions of the patent statues, the present invention has been described in what is considered to represent its preferred embodiments. However, it should be noted that the invention can be practiced otherwise than as specifically illustrated and described without departing from its spirit or scope.

What is claimed is:

1. A bifacial photovoltaic module for building and construction comprising:
a sheet of a light-transmitting substrate material having a first and a second major surface, the first major surface of the substrate adapted to be oriented toward a source of solar radiation, and the second major surface adapted to be oriented toward an exterior surface or an interior space of a building;
one or more layers of material which singly, or in combination, comprise a photoactive structure having first and second activation surfaces disposed over the first major surface of the light transmitting substrate; and
at least one reflective element disposed over the second major surface of the substrate, such that a portion of the solar radiation passing through the sheet of light-transmitting substrate is reflected off of the reflective element back through the light-transmitting substrate to the photoactive structure; and
the photoactive structure is contacted by both direct incoming solar radiation on the first activation surface and by a reflected portion of such incoming solar radiation on the second activation surface as directed thereto by the at least one reflective element.

2. The bifacial photovoltaic module defined in claim 1, wherein the module further comprises a device for collecting the direct electrical current generated by conversion of radiant energy by the photoactive structure.

3. The bifacial photovoltaic module defined in claim 2, wherein the module further comprises an inverter for converting the direct electrical current to alternative electrical current.

4. The bifacial photovoltaic module defined in claim 1, wherein the light-transmitting substrate material comprises glass.

5. The bifacial photovoltaic module defined in claim 4, wherein the glass substrate comprises a low-iron content, soda-lime-silica glass.

6. The bifacial photovoltaic module defined in claim 1, wherein the at least one reflective element comprises a metal or metal oxide film having a reflectivity ≧10%.

7. The bifacial photovoltaic module defined in claim 6, wherein the metal or metal oxide film is one chosen from the group consisting of: chromium, aluminum, silver and silica.

8. A bifacial photovoltaic module for building and construction comprising:
a first and second sheet of a light-transmitting substrate material, arranged in a parallel relationship each having a first and a second major surface;
a sheet of a light-transmitting polymeric material having two major surfaces disposed between the two sheets of the light-transmitting substrate and bonded to the second major surface of the first glass sheet and the first major surface of the second glass sheet so as to create a laminate;
a photoactive material disposed on at least one of the major surfaces of the light-transmitting polymeric material to form a photoactive structure; and
at least one reflective element disposed over at least one of the first and second major surface of the second sheet of light-transmitting substrate material, such that a portion of the solar radiation passing through the sheet of light-transmitting substrate is reflected off of the reflective element back through the light-transmitting substrate to the photoactive structure, wherein the photoactive structure is activated by both direct incoming solar radiation and by a reflected portion of such incoming solar radiation as directed thereto by the at least one reflective element.

9. The bifacial photovoltaic module defined in claim 8, wherein the light-transmitting substrate material comprises glass.

10. The bifacial photovoltaic module defined in claim 8, wherein the coated light-transmitting polymeric material is one selected from the group consisting of: pholyvinyl butyral, polyvinyl chloride, EVA, and mylar.

11. The bifacial photovoltaic module defined in claim 8, wherein the at least one reflective element comprises a metal or a metal oxide film having a reflectivity ≧10%.

12. The bifacial photovoltaic module defined in claim 11, wherein the at elast one reflective element comprises a metal or a metal oxide film having a reflectivity ≧50%.

13. A bifacial photovoltaic module for building and construction comprising:
a first and second substantially transparent glass sheet in a parallel relationship having bondingly disposed therebetween a polymeric photoactive structure to form a laminate;
at least a third glass sheet having first and second major surfaces in a parallel, spaced apart relationship with the laminate;
a spacer element defining a space between the laminate and the at least third glass sheet;
at least one reflective element disposed over at least one of the first and second major surface of the at least third glass sheet, such that a portion of the solar radiation passing through the laminate and the space between the laminate and the at least third glass sheet is reflected off of the at least one reflective element back to the photoactive structure, wherein the photoactive structure is activated by both direct incoming solar radiation and by a reflected portion of such incoming solar radiation as directed thereto by the at least one reflective element.

14. The bifacial photovoltaic module defined in claim 13, wherein the at least one reflective element is substantially opaque.

15. The bifacial photovoltaic module defined in claim 13, wherein the at least one reflective element is light-transmitting.
